(19) United States
(12) Patent Application Publication
(10) Pub. No.: US 2003/0064169 A1
(43) Pub. Date: Apr. 3, 2003

(54) Plasma enhanced chemical vapor deposition apparatus and method of producing carbon nanotube using the same

(76) Inventors: Jin Pyo Hong, Seoul (KR); Chae Ok Kim, Kyungki-do (KR); Hyoung Joo Yoon, Seoul (KR); Ho Suck Kang, Seoul (KR)

Correspondence Address: POWELL, GOLDSTEIN, FRAZER & MURPHY LLP, P.O. BOX 97223, WASHINGTON, DC, 20090-7223, US

(21) Appl. No.: 10/252,531

(22) Filed: Sep. 24, 2002

(30) Foreign Application Priority Data
Sep. 28, 2001 (KR) 2001-60349

(51) Int. Cl. C23C 16/00; H05H 1/24

(52) U.S. Cl. 427/569; 118/723 E

(57) ABSTRACT

The present invention provides a plasma enhanced chemical vapor deposition apparatus wherein a grid is positioned between a gas supply section serving as an upper electrode and a substrate holder serving as a lower electrode, to change an electric field in a process chamber and increase a relative number of reactive fine particles. By applying a voltage to the grid, a structural characteristic of a material growing on the substrate can be adjusted, and by employing a position adjustment section for adjusting a position and an inclination of the grid, properties of the growing material, such as vertical orientation, a length, an orientation angle, etc., can be adjusted. The present invention also provides a method of producing a carbon nanotube using the plasma enhanced chemical vapor deposition apparatus. According to the method, it is possible to grow the carbon nanotube at a low temperature of about 300-550° C., preferably 350-550° C. Also, by adding the step of applying a voltage to the grid, a diameter, a length and an orientation angle of the carbon nanotube can be optimally adjusted. Further, by adjusting a position and an inclination of the grid, influence of the voltage applied to the grid and an orientation angle can be adjusted.

### BACKGROUND OF THE INVENTION

1. Field of the Invention

The present invention relates to a plasma enhanced chemical vapor deposition apparatus and a method of producing a carbon nanotube using the same, and more particularly, to a plasma enhanced chemical vapor deposition apparatus which has a grid for enabling a deposition process to be implemented at a low temperature, and a method of producing a carbon nanotube using the same.

2. Description of the Related Art

A carbon nanotube was first introduced to the world by Sumio Lijima through a paper entitled “Helical microtubles of graphitic carbon”, Nature, vol. 354, Nov. 7, 1991, pp. 56-58. According to the paper, it was shown that a material containing carbon nanotubes (of about 15%) can be produced by arc discharge between graphite rods.

In a carbon nanotube, one carbon atom is bound with three other carbon atoms to from a hexagonal honeycomb-shaped structure, and a film of such honeycomb-shaped structures is rolled in the form of a tube. That is to say, the carbon nanotube has a hollow tube-shaped configuration, and possesses a diameter of several through several tens of nanometers.

Such a carbon nanotube can selectively have characteristics of an electrical conductor such as metal or those of an electrical semiconductor, depending upon a degree to which the carbon nanotube is rolled and a diameter of the tube. Also, having excellent mechanical, electrical and chemical properties, the carbon nanotube can be variously applied to an FED (field emission display), a hydrogen storing container, an electrode of a secondary battery, and so forth. Further, it is anticipated that the carbon nanotube serves as a material capable of being applied to a semiconductor device of a tera-grade.

However, the method for producing a carbon nanotube by utilizing arc discharge as described in the paper has a problem in that, since a percentage of a carbon nanotube contained in an entire produced material is low, about 15%, it is necessary to implement a complicated purification process. As a consequence, industrial applicability of the carbon nanotube produced in this way cannot but be deteriorated.

In order to cope with this problem to some extent, referring to a paper of Michiko Kusunoki, et al., entitled “Epitaxial carbon nanotube film self-organized by sublimation decomposition of silicon carbide”, Appl. Phys. Lett., vol. 71, 1997, pp. 2620, there is disclosed a new method in which laser is irradiated to graphite or silicon carbide to produce a carbon nanotube at a high temperature (in the case of graphite, greater than 1200° C., or silicon carbide, 1600˜1700° C.).

Nevertheless, this method still has a problem in that a purification process must be necessarily implemented on a produced material, it is not feasible to grow the carbon nanotube on a substrate, and, as in the above-described method for producing a carbon nanotube by utilizing arc discharge, the carbon nanotube is produced at a high temperature of 1000° C. As a result, it is impossible to industrially apply the method.

With these considerations, a method for growing a carbon nanotube on a predetermined substrate has been disclosed in a paper by W. Z. Li, et al., entitled “Largescale synthesis of aligned carbon nanotubes”, Science, vol. 274, Dec., 1996, pp. 1701-1703. In this method, a hydrocarbon-based gas is thermally decomposed using chemical vapor deposition to produce a carbon nanotube. In the method, it is possible to align carbon nanotubes on a substrate and grow the carbon nanotubes at a lower temperature when compared to the method using arc discharge or laser vaporization. Nonetheless, due to the fact that vertical orientation of a carbon nanotube growing while a temperature of the substrate is decreased is deteriorated, it is necessary to raise a temperature of the substrate to greater than about 600° C.

Therefore, since it is impossible to produce a carbon nanotube of high quality using a glass substrate which is affected by a process temperature, the carbon nanotube cannot be applied to a device such as an FED (field emission display).

Referring to Korean Patent Application No. 2000-29583 filed on May 31, 2000, there is disclosed a method for producing a carbon nanotube using plasma enhanced chemical vapor deposition (PECVD). In this method, a carbon nanotube grows in a manner such that a source gas is decomposed using RF (radio frequency) plasma. However, in reality, since the method cannot be implemented at a temperature of less than 600° C., it is considered to be inappropriate for growth at a low temperature.

Further, as other conventional technologies for producing a carbon nanotube, there are disclosed in the art a plasma enhanced chemical vapor deposition method using a hot filament (Z. F. Ren, Science, vol. 282, 1998, pp. 1105), a chemical vapor deposition method using high-density (ECR; electron cyclotron resonance) plasma (Korean Patent Application No.2000-19559 filed on Apr. 14, 2000), and a chemical vapor deposition method using microwave plasma (L. C. Qin, Applied physics letters, vol. 72, 1998, pp. 3437).

Concretely speaking, the plasma enhanced chemical vapor deposition method using a hot filament, the chemical vapor deposition method using high-density plasma, and the chemical vapor deposition method using microwave plasma have been developed since, in the conventional RF plasma enhanced chemical vapor deposition method, a carbon nanotube can grow at a substrate temperature of about 600° C. which is used in a thermo-chemical vapor deposition method. In these three methods, while it is possible to decrease a temperature of a heater for heating a substrate when implementing deposition, in reality, a problem is caused in that, due to other factors, a temperature of the substrate is increased up to about 600° C.

That is to say, in the case of the plasma enhanced chemical vapor deposition method using a hot filament, the substrate is actually heated by hot electrons emitted from the filament. In the case of the chemical vapor deposition method using microwave plasma, as the substrate is heated up to greater than 600° C. by a temperature of the plasma itself, defects are caused as in the case of the thermo-chemical vapor deposition method. In the case of the chemical vapor deposition method using high-density plasma, it was found that a carbon nanotube cannot properly grow at a substrate temperature of less than 600° C. Also, the above-described conventional methods have drawbacks in that the lower a process temperature is set within an allowable range, the more the vertical orientation of a carbon nanotube produced is deteriorated.

As can be readily seen from above descriptions, in the methods for producing a carbon nanotube which have been recently developed, in order to produce a carbon nanotube having a satisfactory level of industrial applicability, at least a temperature of greater than 600° C. must be maintained. Therefore, at a process temperature of less than 600° C., properties of the carbon nanotube cannot but be degraded.

Hence, the development of an apparatus and a method for producing a carbon nanotube which can upgrade properties of the carbon nanotube growing on a substrate even at a low process temperature of less than 600° C., is required.

### SUMMARY OF THE INVENTION

Accordingly, the present invention has been made in an effort to solve the problems occurring in the related art, and an object of the present invention is to provide a plasma enhanced chemical vapor deposition apparatus which can grow a carbon nanotube on a substrate at a low temperature of less than 600° C., improve vertical orientation of the grown carbon nanotube, and adjust a diameter and a length of the grown carbon nanotube.

Another object of the present invention is to provide a method of producing a carbon nanotube using the apparatus. In order to achieve the first object, according to one aspect of the present invention, there is provided a plasma enhanced chemical vapor deposition apparatus comprising: a process chamber; a gas supply section formed at an upper part of the process chamber to supply a predetermined gas; a substrate holder disposed at a lower part of the process chamber to support a substrate; a first power supply section for applying a high frequency voltage by using the gas supply section and the substrate holder as both electrodes, so that the predetermined gas supplied by the gas supply section is formed into plasma; and a grid made of a conductive substance and positioned between the gas supply section and the substrate holder.

Also, according to another aspect of the present invention, the apparatus may further comprise a second power supply section for applying a direct current or an RF voltage to the grid. In particular, the grid may possesses a mesh-shaped contour having a plurality of hexagonal holes or a plurality of circular holes defined therein.

Further, the grid may be positioned parallel with respect to and at predetermined separations from the gas supply section and the substrate holder. The plasma enhanced chemical vapor deposition apparatus according to the present invention may further selectively comprise first and second position adjustment sections for moving a position of the grid. The first position adjustment section performs a function of adjusting distances between the grid and the gas supply section and between the grid and the substrate holder, and the second position adjustment section performs a function of adjusting an angle defined between the grid and a lower end surface of the gas supply section or between the grid and an upper end surface of the substrate holder.

In order to achieve the second object, according to another aspect of the present invention, there is provided a carbon nanotube production method using the plasma enhanced chemical vapor deposition apparatus having disposed therein the grid. The method comprises the steps of: forming a catalytic metal film on a substrate; placing the substrate on a substrate holder of a plasma enhanced chemical vapor deposition apparatus in which a gas supply section and a substrate holder serve as both electrodes for applying a high frequency voltage and a grid is positioned in a space between the gas supply section and the substrate holder; forming catalytic fine particles on the catalytic metal film by supplying an etching gas through the gas supply section; and producing the carbon nanotube on the catalytic fine particles by supplying a carbon source gas through the gas supply section. The carbon nanotube producing method according to the present invention may be implemented within a low temperature range of about 300-550° C.

According to another aspect of the present invention, the step of forming the catalytic metal film on the substrate may comprise the sub steps of forming a buffer metal film on the substrate; and forming the catalytic metal film on the buffer metal film.

Moreover, when producing the carbon nanotube, by applying a predetermined voltage to the grid, vertical orientation of the carbon nanotube can be improved. It is preferred that the voltage is a negative voltage for influencing the vertical orientation. In consideration of actual applicability, it is more preferred that a negative voltage of less than about −1000V is applied to the grid. Furthermore, before producing the carbon nanotube, by adjusting a position of the grid in downward and upward directions between the gas supply section and the substrate holder, or by adjusting an inclination of the grid so as to change an angle defined between the grid and a lower end surface of the gas supply section or between the grid and an upper end surface of the substrate holder, it is possible to control not only vertical orientation but also a diameter and a length of the carbon nanotube produced on the substrate.

In addition, by purifying in situ the carbon nanotube when implementing the step of producing the carbon nanotube, a purity of the carbon nanotube can be increased.

### BRIEF DESCRIPTION OF THE DRAWINGS

The above objects, and other features and advantages of the present invention will become more apparent after a reading of the following detailed description when taken in conjunction with the drawings, in which:

FIG. 1 is a schematic view illustrating a plasma enhanced chemical vapor deposition apparatus in accordance with an embodiment of the present invention;

FIGS. 2a through 2c are schematic views illustrating various shapes of grids which are adopted in the present invention;

FIG. 3 is a cross-sectional view illustrating a substrate used for producing a carbon nanotube according to the present invention;

FIGS. 4a and 4b are pictures obtained by photographing a surface condition of a catalytic metal film using an atomic force microscope before and after plasma processing;

FIGS. 5a and 5b are photographs of a horizontal plane and a vertical section of the carbon nanotube produced according to the present invention, obtained by a scanning electron microscope;

FIGS. 6a and 6b are photographs of the carbon nanotube produced according to the present invention, obtained by a transmission electron microscope;

FIG. 7 is a Raman spectroscopic spectrum of the carbon nanotube produced according to the present invention;

FIGS. 8a and 8b are photographs of carbon nanotubes produced by varying a separation of a grid, obtained by a scanning electron microscope; and

FIGS. 9a through 9g are photographs of carbon nanotubes produced by varying a kind and a magnitude of a voltage applied to the grid, obtained by a scanning electron microscope.

### DETAILED DESCRIPTION OF PREFERRED EMBODIMENTS

Reference will now be made in greater detail to a preferred embodiment of the invention, an example of which is illustrated in the accompanying drawings. Wherever possible, the same reference numerals will be used throughout the drawings and the description to refer to the same or like parts.

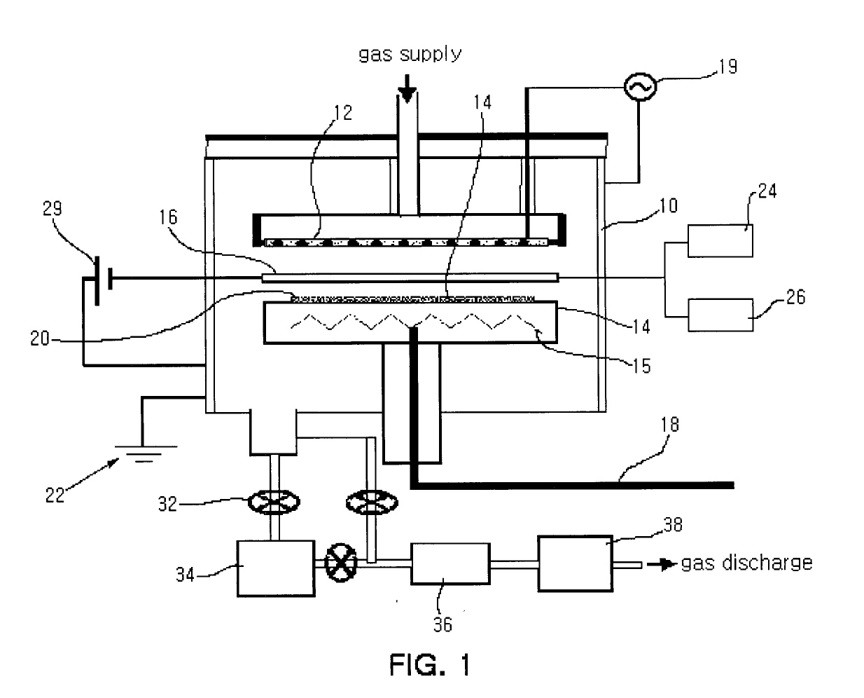

FIG. 1 is a schematic view illustrating a plasma enhanced chemical vapor deposition apparatus in accordance with an embodiment of the present invention. Referring to FIG. 1, the plasma enhanced chemical vapor deposition apparatus comprises a process chamber 10 in which plasma is generated and deposition of a specified material is implemented. A gas supply section 12 is mounted at an upper part of the process chamber 10 to supply a predetermined gas, and a substrate holder 14 is mounted at a lower part of the process chamber 10 to support a substrate 20. A window (not shown) may be additionally installed at a side of the process chamber 10 so that the deposition process can be observed with naked eyes.

The plasma enhanced chemical vapor deposition apparatus according to the present invention includes a RF (radio frequency) power supply section 19. The RF power supply section 19 functions to apply an RF voltage, with the gas supply section 12 and the substrate holder 14 serving as upper and lower electrodes, to thereby convert the gas supplied from the gas supply section 12 into a plasma state. A gas discharge section is provided below the process chamber 10 to discharge the used gas out of the process chamber 10.

While the gas discharge section can be configured in diverse forms, in this preferred embodiment of the present invention, it includes a shutoff valve 32, a turbo molecular pump 34, a rotary pump 36 and a scrubber 38.

In the plasma enhanced chemical vapor deposition apparatus, by using a substrate heating element 15 which is embedded in the substrate holder 14 and comprises a resistor, the substrate 20 can be heated to an appropriate temperature. Here, the appropriate temperature means a temperature for maintaining the substrate 20 in a state capable of allowing a material deposited on the substrate 20 to grow into a desired configuration.

For example, when producing a carbon nanotube, in the case of the conventional plasma enhanced chemical vapor deposition apparatus, a substrate temperature or a process temperature must be maintained at greater than 600° C.

Therefore, due to the fact that the substrate must be maintained at an appropriate temperature while implementing a plasma vapor deposition process, restrictions cannot but be imposed on selection of a substrate material. In this sense, it has been recognized as an important task in the art to lower a temperature of a substrate as much as possible and develop a plasma enhanced vapor deposition apparatus capable of growing a material such as a carbon nanotube to have desired properties.

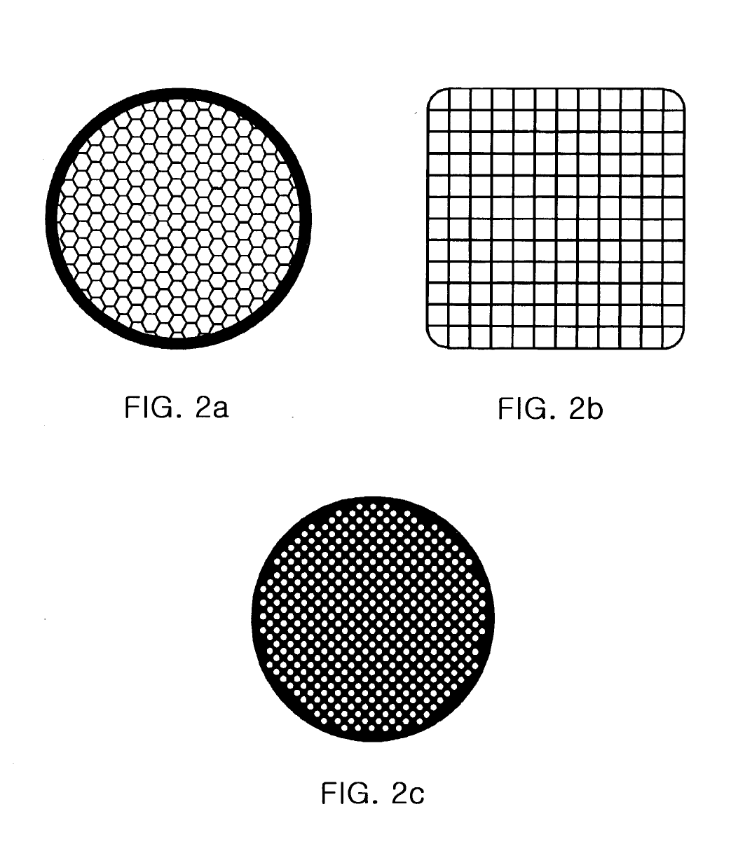

The inventors of the present invention found through repeated experiments that, by positioning a grid 16 as shown in FIGS. 2a through 2c between the gas supply section 12 and the substrate holder 14 serving as upper and lower electrodes, it is possible to increase the number of reactive fine particles in the process chamber 10 and implement a plasma vapor deposition process with the substrate 20 maintained at a lower temperature.

Describing the principle in detail, when plasma generated between the gas supply section and the substrate holder is ionized into cations and electrons of a reactive gas, since electrons are discharged through the plasma enhanced vapor deposition apparatus which is ground via the grid made of the conductive substance, the number of cations serving as reactive fine particles directly involved in growth is relatively increased. By this fact, it is analyzed that growth of a material can be significantly promoted. Also, as the plasma generated between the gas supply section and the substrate holder when a voltage is applied to the grid passes through a mesh structure of the grid, an additional amount of plasma is locally generated, whereby vertical orientation can be improved.

Generally, the term, “grid” used in the art refers to a lattice or mesh-shaped electrode positioned between positive and negative electrodes. Usually, the grid may be made of SUS (a kind of stainless steel alloy). While it is known that the grid is mainly used in a vacuum tube, etc. to perform a function of simply adjusting an electric field of an electron current path, as described above, the present inventors found that, by inserting the grid 16 between both electrodes of the conventional RF plasma enhanced chemical vapor deposition apparatus, it is possible to increase the relative number of reactive fine particles in the process chamber 10. By applying this fact to a process for production of a carbon nanotube, it was proved that a carbon nanotube having excellent properties can be grown at a process temperature of 300-550° C. Specifically, it was found that a carbon nanotube having more excellent properties can be grown in a temperature range of 350-550° C.

Further, as can be readily seen from FIG. 1, in the plasma enhanced chemical vapor deposition apparatus according to the present invention, a power supply section 29 for supplying power to the grid 16 can be additionally disposed. In a plasma deposition process, by applying a direct current having a polarity or an RF voltage to the grid 16, it is possible to adjust a configuration and an aligned status of a material deposited on the substrate 20. In particular, in the process of producing a carbon nanotube, by applying a negative voltage to the grid, advantages are obtained in that vertical orientation of the carbon nanotube can be improved and a diameter and a length of the carbon nanotube can be appropriately adjusted to control growth of the carbon nanotube.

Moreover, according to another aspect of the present invention, a first position adjustment section 24 for vertical movement of the grid 16 and a second position adjustment section 26 for adjusting an inclination of the grid 16 are additionally provided. The first position adjustment section 24 performs a function of moving the grid 16 in upward and downward directions between the gas supply section 12 and the substrate holder 14 to adjust distances. The second position adjustment section 26 performs a function of adjusting an inclination of the grid 16 to thereby change an angle defined between the grid 16 and a lower end surface of the gas supply section 12 or between the grid 16 and an upper end surface of the substrate holder 14. In conformity with a desire of a user, the first or second position adjustment sections 24 and 26 can be selectively provided to adjust a position or an inclination of the grid 16.

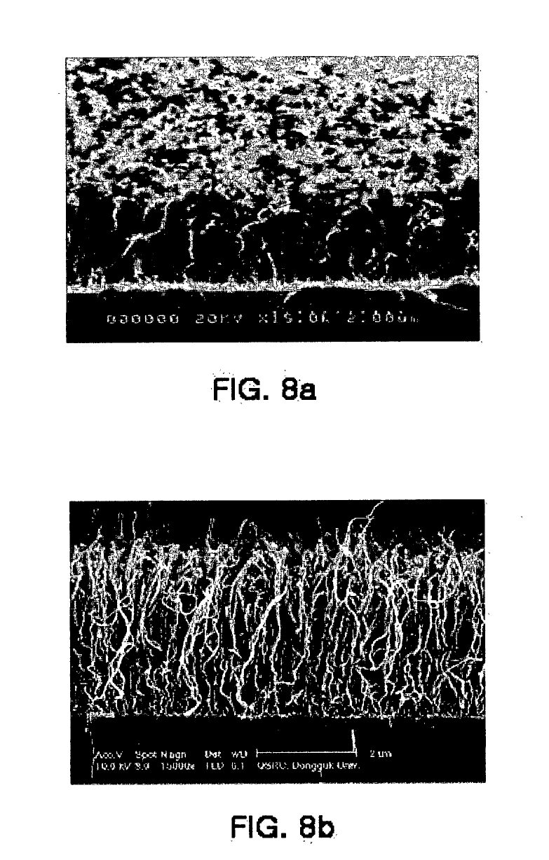

Accordingly, due to this feature of the present invention, using the first position adjustment section 24, it is possible to adjust distances between the grid 16 and gas supply section 12 and between the grid 16 and substrate holder 14. At this time, by additionally moving the substrate holder 14 in upward or downward directions as in the conventional art, it is possible to lengthen or shorten both of the distances. In this way, vertical orientation of carbon nanotubes can be controlled in a more efficient manner. For example, FIGS. 8a and 8b are SEM photographs of carbon nanotubes produced by varying a separation of the grid. In the case of FIG. 8a, carbon nanotubes were produced in a state wherein the distances between the grid 16 and gas supply section 12 and between the grid 16 and substrate holder 14 are commonly set to 1.5 cm. And, in the case of FIG. 8b, carbon nanotubes were produced in a state wherein the first and second distances are set to 2 cm and 3 cm, respectively. Referring to FIGS. 8a and 8b, it is to be understood that the carbon nanotubes of FIG. 8b have superior vertical orientation and grow longer than the carbon nanotubes of FIG. 8a. The reason for this is that, by increasing the second distance measured between the grid 16 and the substrate holder 14, plasma etching effect is reduced and an average free path of plasma is lengthened, whereby a time-prolonged effect is induced in the reactive fine particles on the substrate.

For example, the second position adjustment section 26 can adjust an inclination of the grid 16 positioned parallel to the respective lower surface of the gas supply section 12 and upper surface of the substrate holder 14, to thereby regulate an orientation angle of the carbon nanotube. This is due to the fact that an orientation angle of a carbon nanotube is perpendicular to a surface of the grid 16. Due to this orientation angle adjustment of the carbon nanotube, a large voltage can be applied to the grid 16.

As described above, in the plasma enhanced chemical vapor deposition apparatus according to the present invention, by varying a voltage applied to the grid 16 or adjusting a position and an inclination of the grid 16, it is possible to control properties of a carbon nanotube growing before or while implementing a production process. This technical peculiarity of the present invention cannot be anticipated in the conventional apparatus.

The plasma enhanced chemical vapor deposition apparatus according to the present invention is basically characterized in that the grid is positioned between both electrodes which are used to supply a voltage with an aim of generating plasma. Due to this fact, as a process can be implemented at a low temperature, choice for a substrate material can be widened, and, by supplying a predetermined voltage to the grid, a configuration and an aligned status of a material growing on the substrate can be properly adjusted.

Thus, the plasma enhanced chemical vapor deposition apparatus according to the present invention is adapted to be used in a carbon nanotube production procedure. Concretely speaking, since the plasma enhanced chemical vapor deposition apparatus according to the present invention can produce a carbon nanotube at a low temperature range of about 300-550° C., it is possible to manufacture a field emission display (FED) by using glass as the substrate. Furthermore, because properties of a carbon nanotube vary depending upon vertical orientation and a diameter and a length of the carbon nanotube, by changing a voltage applied to the grid in the production process, it is possible to obtain a carbon nanotube having desired properties.

In the present invention, the grid is not limited to a particular contour but may have a variety of contours. In this preferred embodiment of the present invention, the grid has a lattice or mesh-shaped contour in which a plurality of holes are regularly defined. This is to ensure that an increase in the number of reactive fine particles and orientation upon application of a voltage uniformly influence the entire substrate.

Contours of the grid which can be adopted in the present invention are shown in FIGS. 2a through 2c. FIG. 2a shows a circular mesh-shaped grid in which hexagonal holes are defined, FIG. 2b shows a square lattice-shaped grid which has square holes, and FIG. 2c shows a conventional circular mesh-shaped grid in which circular holes are regularly distributed. A person skilled in the art will readily appreciate that, in addition to the above-described contours, various other contours can be adopted for the grid.

According to the present invention, there is provided a method for producing a carbon nanotube using a principle of the plasma enhanced chemical vapor deposition. As described above, the plasma enhanced chemical vapor deposition apparatus according to the present invention can be suited to a procedure for producing a carbon nanotube.

The method for producing a carbon nanotube according to the present invention comprises a first step of forming a catalytic metal film on a substrate, a second step of placing the substrate on a substrate holder of a plasma enhanced chemical vapor deposition apparatus having a grid, a third step of forming catalytic fine particles on the catalytic metal film by supplying a plasma processing gas through the gas supply section, and a fourth step of producing a carbon nanotube on the catalytic fine particles by supplying a carbon source gas through the gas supply section.

Hereafter, the method for producing a carbon nanotube according to a preferred embodiment of the present invention will be described.

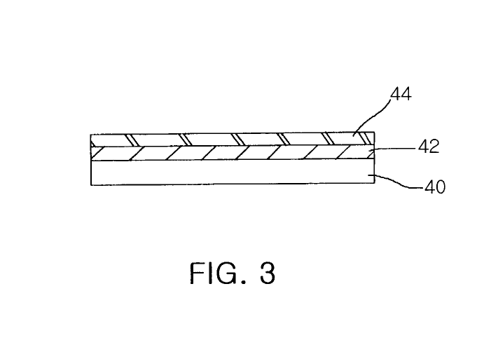

FIG. 3 illustrates a preferred example of a substrate on which a catalytic metal film is formed at the first step. Referring to FIG. 3, first, a buffer layer 42 is formed on a substrate 40. Using a thickness thereof and a particle size, the buffer layer 42 performs a function of uniformly controlling a surface of a catalytic metal film 44 to be formed on the buffer layer 42 and increasing adhesion force between the catalytic metal film 44 and the substrate 40. Here, the buffer layer 42 may be formed of one selected from a group consisting of Cr, Ta and Ti. Next, the catalytic metal film 44 is formed on the buffer layer 42. The catalytic metal film 44 may be formed of one selected from a group consisting of Ni, Fe, Co and alloys thereof. A person skilled in the art will readily recognize that, in addition to the above-described substances, other transition metals may also be used to form the buffer layer 42 and the catalytic metal film 44.

At the second step, the substrate having the catalytic metal film formed thereon is placed on a substrate holder of a plasma enhanced chemical vapor deposition apparatus having a grid. The plasma enhanced chemical vapor deposition apparatus used herein has the grid which is positioned in a space defined between upper and lower electrodes used for supplying RF power. For example, in this second step, the plasma enhanced chemical vapor deposition apparatus as shown in FIG. 1 can be employed.

If the second step of placing the substrate on the substrate holder is completed, the third step of plasma-processing the catalytic metal film is implemented. This plasma processing is implemented in a manner such that catalytic fine particles are formed on the surface of the catalytic metal film so as to allow formation of carbon nanotubes. At this time, an ammonia or hydrogen gas can be used as a gas for the plasma processing, and, by adding an inert gas such as helium, and the like, it is possible to activate the plasma processing. Describing process conditions, it is preferred that a process chamber has a temperature of 300-550° C. and a pressure of 0.1 to several tens of torrs, the ammonia or hydrogen gas is supplied at a flow rate of several tens to several hundreds of seems, and RF power of about 200-300 W is applied for 1-30 minutes.

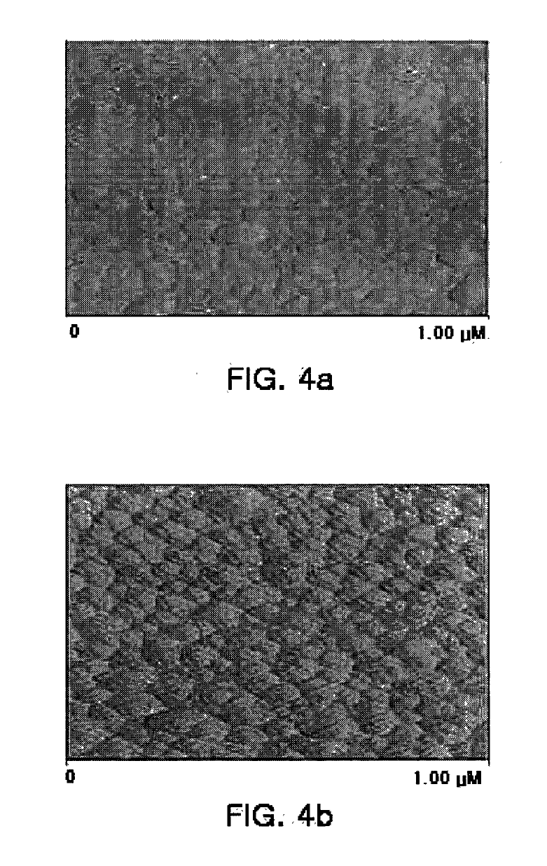

FIGS. 4a and 4b show the surface of the catalytic metal film before and after plasma processing. Differently from a surface state of FIG. 4a, in FIG. 4b, as the catalytic metal film is plasma-processed, catalytic fine particles composed of fine grains suitable for production of carbon nanotubes are formed on the catalytic metal film.

At the fourth step, a carbon nanotube is produced on the surface of the catalytic metal film obtained at the third step. In the fourth step, a carbon source gas is supplied after the ammonia or hydrogen gas supplied for the formation of the catalytic fine particles is removed, and then, by applying an RF voltage, a carbon nanotube is produced. An acetylene gas, methane gas, propane gas or ethylene gas can be used as the carbon source gas. In this regard, a gas of several tens to several hundreds of seems is supplied. Here, in order to activate the growth of the carbon nanotube, it is preferable to supply a predetermined amount of hydrogen and ammonia gas. The inside of the process chamber is maintained at a temperature of 300-550° C. and a pressure between several hundreds of mtorrs and 10 torrs, and power of 20-600 W is applied for the generation of plasma.

The reason why the carbon nanotube can grow at a low temperature of less than 550° C. is due to influence by the grid positioned between the upper and lower electrodes. In the experiments executed with the grid removed and at the same conditions as described above, a carbon nanotube was not produced at a temperature of less than 550° C.

This is because, as described above, an amount of cations serving as the reactive fine particles is relatively increased due to the presence of the grid. Of course, it is to be noted that the grid adopted in the carbon nanotube production method according to the present invention may have a variety of contours as exemplified in FIGS. 2a through 2c.

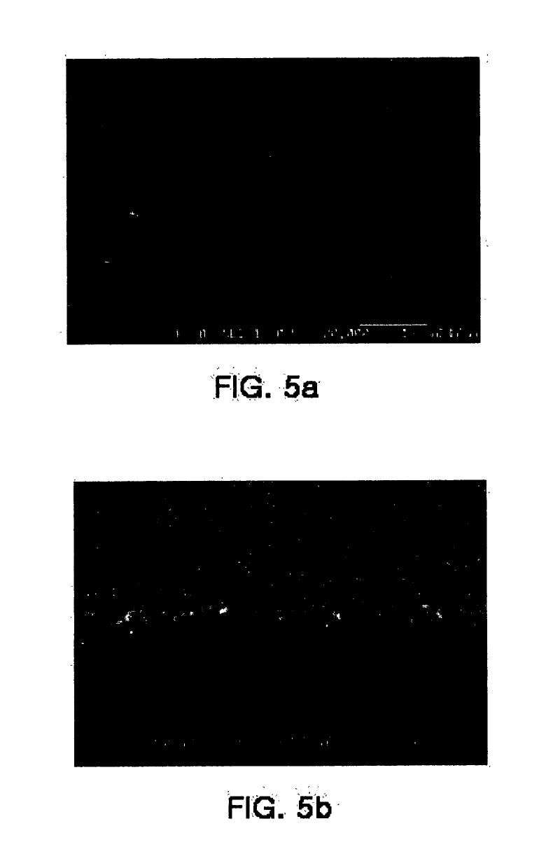

FIGS. 5a and 5b are photographs of a horizontal plane and a vertical section of carbon nanotubes produced at 400° C. according to the present invention, obtained by a scanning electron microscope. Referring to FIG. 5a, a number of carbon nanotubes are formed to have a diameter of about 50 nm, and it to be confirmed from FIG. 5b that an aligned status of carbon nanotubes is very excellent.

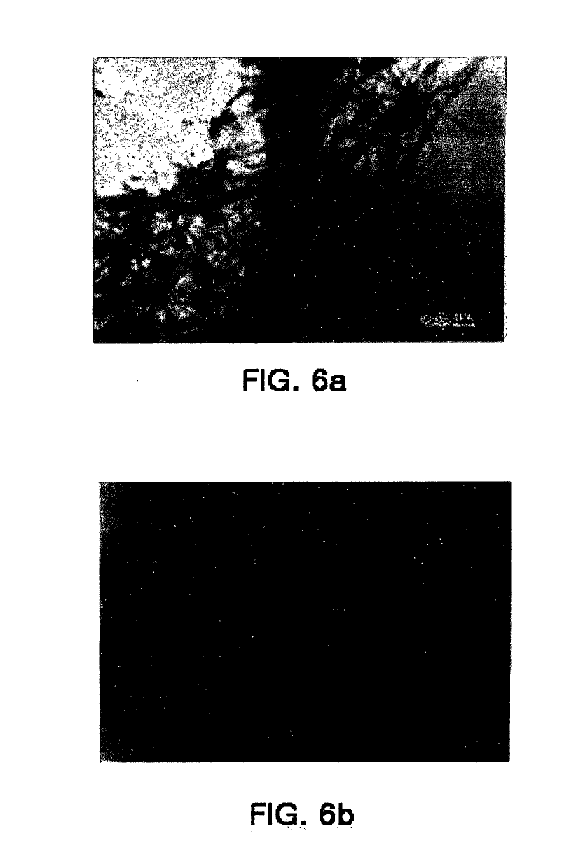

FIGS. 6a and 6b are photographs of the carbon nanotube produced according to the present invention, obtained by a transmission electron microscope. FIG. 6a illustrates a horizontal configuration of a carbon nanotube, and FIG. 6b is a photograph of the carbon nanotube enlarged to high magnifications. From FIG. 6b, it is possible to confirm a multi-walled carbon nanotube which has a hollow tubular configuration and multiple walls.

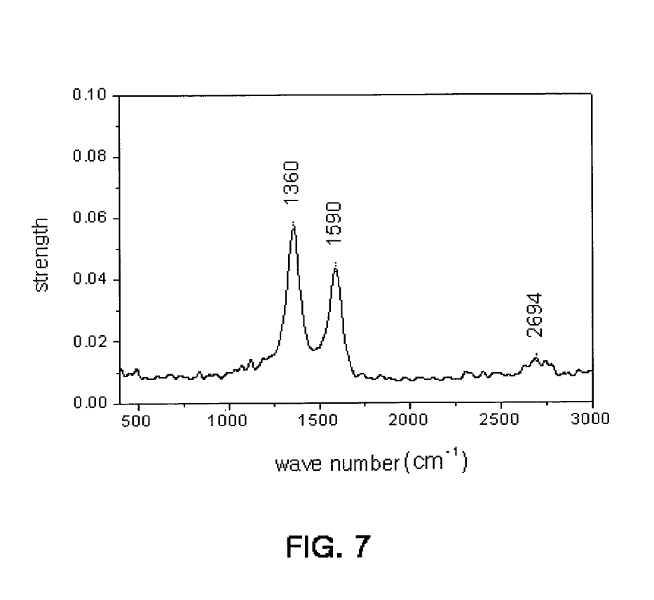

FIG. 7 is a Raman spectroscopic spectrum of the carbon nanotube produced according to the present invention. The abscissa represents a wave number and the ordinate represents a strength. It is to be readily understood from FIG. 7 that a peak value is obtained at 1590 cm⁻¹ as an inherent characteristic of a carbon nanotube.

In another variation of the method for producing a carbon nanotube according to the present invention, at the fourth step for producing the carbon nanotube, by applying a predetermined voltage to the grid, vertical orientation can be improved and it is possible to adjust a diameter and a length of the carbon nanotube.

As aforementioned above, the grid is positioned relatively close to the substrate to influence a configuration of the carbon nanotube growing depending upon a voltage applied to the grid.

In order to confirm this fact by experiments, seven substrates which are formed with catalytic metal films of the same thickness were prepared. Then, the seven substrates were placed on a substrate holder of a plasma enhanced chemical vapor deposition apparatus in which a grid is placed between an upper electrode (or a gas supply section) and a lower electrode (or the substrate holder). At this time, by adjusting relative positions of the substrate holder and the grid, the distances between the grid and gas supply section and between the grid and substrate holder were fixed to 2 cm and 3 cm, respectively. Next, plasma processing was implemented for the seven substrates having the catalytic metal films formed thereon, at the same conditions.

The plasma processing was implemented to create catalytic fine particles, while 40 sccm of ammonia gas is supplied and 30 W of power is applied for 5 minutes. Thereafter, in place of the ammonia gas, acetylene and hydrogen gases are supplied at 5 sccm and 20 sccm, respectively, and 200 of power is applied. In these same conditions, carbon nanotubes were formed on the five substrates.

While growing the carbon nanotubes, a kind and a magnitude of a voltage applied to the grid were varied. In one example, carbon nanotubes were produced without voltage application, that is, at 0V. In other three examples, carbon nanotubes were produced while varying a DC voltage to −50V, −70V and −100V. In still other three examples, carbon nanotubes were produced while varying an RF voltage to 50V, 100V and 150V. Thereafter, configurations of the carbon nanotubes formed on the respective substrates were photographed using a scanning electron microscope (SEM).

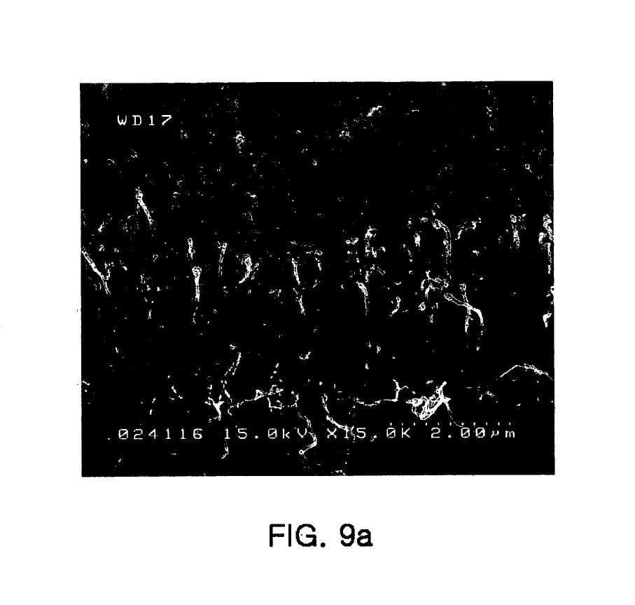

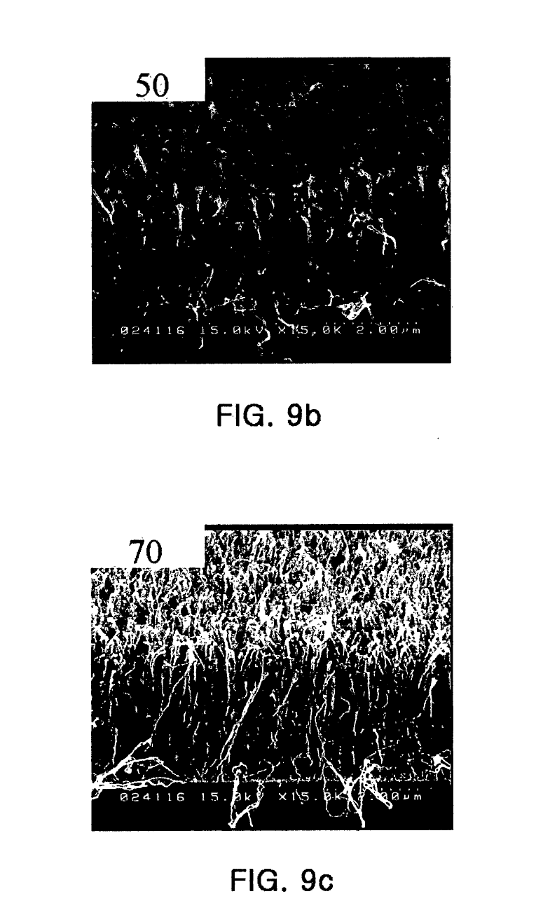

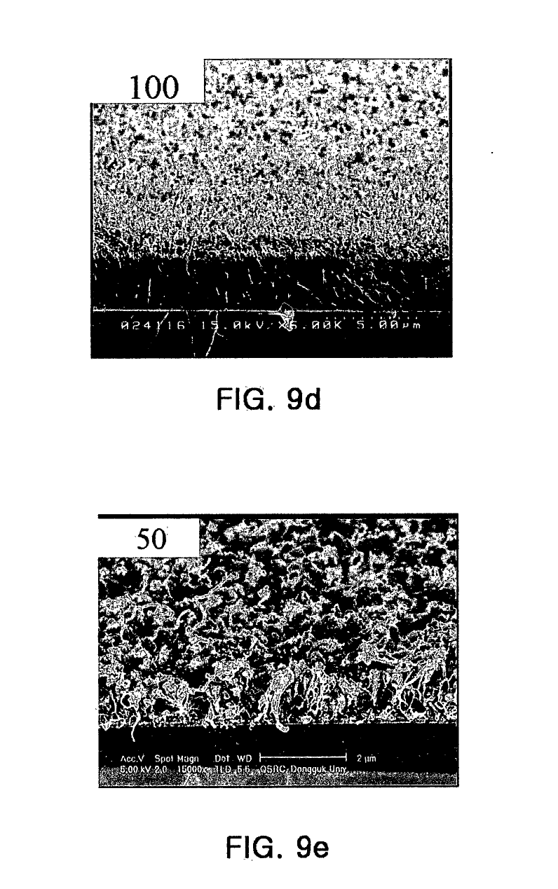

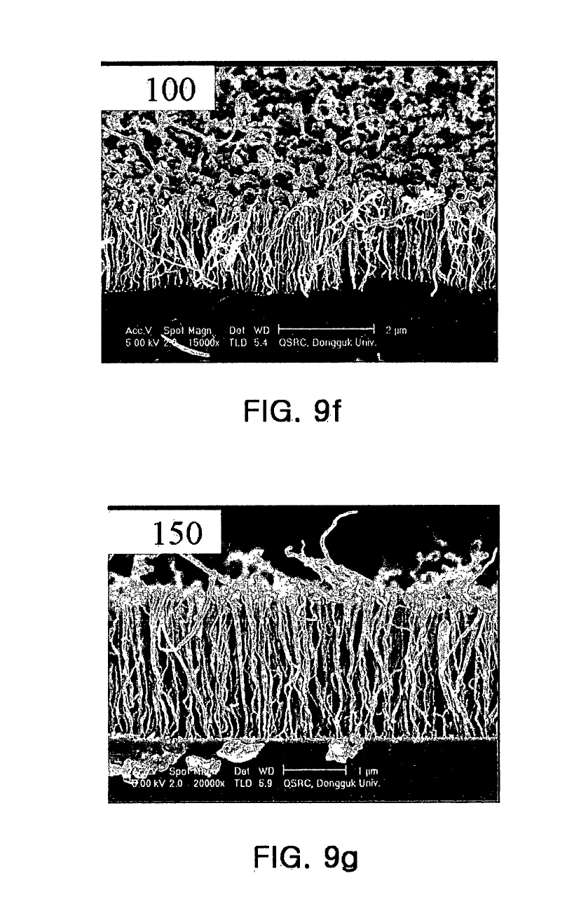

FIGS. 9a through 9g are SEM photographs of carbon nanotubes produced by varying a voltage applied to the grid. FIG. 9a designates the case that 0V is applied. It is to be readily understood that vertical orientation is slightly deteriorated in the case of FIG. 9a when compared to FIG. 9b designating the case that −50V is applied. Vertical orientation and a length of carbon nanotubes are improved and increased in the case of FIG. 9c (application voltage: −70V). Most excellent vertical orientation is obtained in the case of FIG. 9d (application voltage: −100V). As a consequence, it is to be appreciated that, as an application voltage is increased, an amount of reactive fine particles captured by the grid is increased, whereby vertical orientation of the carbon nanotubes is improved and a density per unit area is augmented. Also, if an RF voltage (having a characteristic of an AC voltage) is applied, properties are relatively deteriorated in comparison with the case of applying a DC voltage. However, in the case of FIG. 9f (application voltage: 100V), excellent properties were obtained when compared to the case of FIG. 9e (application voltage: 50V). When the highest RF voltage of 150V is applied, most excellent properties were obtained. Therefore, it is to be noted that, even in the case of RF voltage, upon increasing an application voltage, the same result was obtained as in the case of DC voltage.

As apparent from the above description, the plasma enhanced chemical vapor deposition apparatus according to the present invention provides advantages in that, since a grid is positioned between a gas supply section serving as an upper electrode and a substrate holder serving as a lower electrode, an electric field is changed in a process chamber, and a relative number of reactive fine particles is increased, whereby it is possible to implement a deposition process even under a low temperature.

Further, by applying a voltage to the grid, a structural characteristic of a material growing on the substrate can be adjusted, and by employing a position adjustment section for adjusting a position and an inclination of the grid, influence of the voltage applied to the grid and an orientation angle of a material configuration growing on the substrate can be adjusted. Specifically, it is much preferred that the plasma enhanced chemical vapor deposition apparatus according to the present invention is applied to a method for producing a carbon nanotube.

In the carbon nanotube producing method using the plasma enhanced chemical vapor deposition apparatus according to the present invention, it is possible to grow the carbon nanotube at a low temperature of about 300-550° C., and by applying a voltage to the grid, a diameter, a length and an orientation angle of the carbon nanotube can be optimally adjusted. Further, by adjusting a position and an inclination of the grid, influence of the voltage applied to the grid and an orientation angle can be adjusted.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A plasma enhanced chemical vapor deposition apparatus comprising:
a process chamber;
a gas supply section formed at an upper part of the process chamber to supply a predetermined gas;
a substrate holder disposed at a lower part of the process chamber to support a substrate;
a first power supply section for applying a high frequency voltage by using the gas supply section and the substrate holder as both electrodes, so that the predetermined gas supplied by the gas supply section is formed into plasma; and
a grid made of a conductive substance and positioned between the gas supply section and the substrate holder.

2. The apparatus as set forth in claim 1, further comprising:
a second power supply section for applying a direct current or an RF voltage to the grid.

3. The apparatus as set forth in claim 1, wherein the grid possesses a mesh-shaped contour having a plurality of hexagonal holes defined therein.

4. The apparatus as set forth in claim 1, wherein the grid possesses a mesh-shaped contour having a plurality of circular holes defined therein.

5. The apparatus as set forth in claim 1, wherein the grid is positioned parallel with respect to and at predetermined separations from the gas supply section and the substrate holder.

6. The apparatus as set forth in claim 1, further comprising:
a first position adjustment section for moving the grid in upward and downward directions between the gas supply section and the substrate holder.

7. The apparatus as set forth in claim 1, further comprising:
a second position adjustment section for adjusting an angle defined between the grid and a lower end surface of the gas supply section or between the grid and an upper end surface of the substrate holder.

8. A method for producing a carbon nanotube, comprising the steps of:
forming a catalytic metal film on a substrate;
placing the substrate on a substrate holder of a plasma enhanced chemical vapor deposition apparatus in which a gas supply section and a substrate holder serve as both electrodes for applying a high frequency voltage and a grid made of a conductive substance is positioned in a space between the gas supply section and the substrate holder;
forming catalytic fine particles on the catalytic metal film by supplying a plasma processing gas through the gas supply section; and
producing the carbon nanotube on the catalytic fine particles by supplying a carbon source gas through the gas supply section.

9. The method as set forth in claim 8, wherein the substrate is made of one selected from a group consisting of glass and silicon.

10. The method as set forth in claim 8, wherein the catalytic metal film is formed of one selected from a group consisting of Ni, Fe, Co and alloys thereof.

11. The method as set forth in claim 8, wherein the catalytic metal film is formed to have a thickness of 20-200 nm.

12. The method as set forth in claim 8, wherein the step of forming the catalytic metal film on the substrate comprises the sub steps of:
forming a buffer metal film on the substrate; and
forming the catalytic metal film on the buffer metal film.

13. The method as set forth in claim 12, wherein the buffer metal film is formed to have a thickness of 10-200 nm.

14. The method as set forth in claim 12, wherein the buffer metal film is formed of one selected from a group consisting of Cr, Ta and Ti.

15. The method as set forth in claim 8, wherein the grid possesses a mesh-shaped contour having a plurality of hexagonal holes defined therein.

16. The method as set forth in claim 8, wherein the grid possesses a mesh-shaped contour having a plurality of circular holes defined therein.

17. The method as set forth in claim 8, wherein the step of producing the carbon nanotube further includes the step of applying a predetermined voltage to the grid.

18. The method as set forth in claim 17, wherein the predetermined voltage applied to the grid is a negative DC voltage.

19. The method as set forth in claim 8, wherein the step of producing the carbon nanotube is implemented within a temperature range of about 300-550° C.

20. The method as set forth in claim 8, further comprising the step of:
adjusting a position of the grid in downward and upward directions between the gas supply section and the substrate holder, before the carbon nanotube is produced.

21. The method as set forth in claim 8, further comprising the step of:
adjusting an inclination of the grid so as to change an angle defined between the grid and a lower end surface of the gas supply section or between the grid and an upper end surface of the substrate holder, before the carbon nanotube is produced.

22. The method as set forth in claim 8, further comprising the step of:
purifying in situ the carbon nanotube when implementing the step of producing the carbon nanotube.
